(19) United States
(12) Patent Application Publication
(10) Pub. No.: US 2009/0000115 A1
(43) Pub. Date: Jan. 1, 2009

(54) SURFACE MOUNTING APPARATUS AND METHOD

(75) Inventors: YIN-KUI ZHU, Shenzhen (CN); FENG-HUI WANG, Shenzhen (CN); CHING-HUNG PI, Tayuan (TW)

Correspondence Address: PCE INDUSTRY, INC.;ATT. CHENG-JU CHIANG, 458 E. LAMBERT ROAD, FULLERTON, CA, 92835, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 11/964,565

(22) Filed: Dec. 26, 2007

(30) Foreign Application Priority Data
Jun. 29, 2007 (CN) 200710076270.0

(51) Int. Cl. H05K 3/32; B23P 19/00; H05K 3/30

(52) U.S. Cl. 29/834; 29/739; 29/832; 29/833

(57) ABSTRACT

An exemplary method for surface mounting an electronic component onto a pad of a printed circuit board is provided. The electronic component and the printed circuit board are located onto a platform. An outline image of the electronic component is captured using a first image sensing device. Coordinates of a geometrical center of the electronic component are determined using a central processing device. An outline image of the pad is captured using a second image sensing device. Coordinates of a geometrical center of the pad are determined using the central processing device. The electronic component is moved onto the pad using a picking-up/placing device according to the coordinate of the geometrical center of the electronic component and the coordinate of the geometrical center of the pad. The electronic component can be registered with the pad exactly using the method.

### BACKGROUND

1. Technical Field

The present invention relates to surface mounting technology, particularly to an apparatus and a method for a surface mounting process.

2. Description of Related Art

Surface mounting technology (SMT) is a method for constructing electronic products in which electronic components are mounted directly onto pads on a surface of a printed circuit board. Generally, in a surface mounting process, when an electronic component is mounted onto a printed circuit board, it is necessary to register the electronic component with a corresponding pad of the printed circuit board. Typically, the electronic component can be registered with the corresponding pad using an automatic registering method or a manual registering method.

In the automatic registering method, the electronic component is registered with the corresponding pad using an automatic surface mounting device including a vision inspection registration system. During mounting the electronic component, an image sensor of the vision inspection registration system captures an image of the entire electronic component, thereby calculating coordinates of the image of the entire electronic component in a system of coordinates established in the in the automatic surface mounting device. Then, according to the coordinates of the image of the entire electronic component, the electronic component is moved to pre-determined coordinates established in the automatic surface mounting device where a printed circuit board is located, and thus the electronic component is registered with the corresponding pad of the printed circuit board to be mounted.

However, a field of vision of the image sensor of the vision inspection registration system is generally narrow (e.g., 50 cm×50 cm). Due to a limitation of the field of vision, the image sensor of the vision inspection registration system cannot sense and capture an image of a entire electronic component with a large size, for example, a connector with a size of 62 cm×6 cm. As a result, coordinates of the image of the entire electronic component with a large size cannot be obtained. Therefore, the electronic component with a large size may not be mounted onto the corresponding pad of the printed circuit board in exact position.

In the manual registering method, although the electronic component with a large size can be mounted on the corresponding pad of the printed circuit board using a manual registration process, an error of manual registration may cause the electronic component be mounted onto the corresponding pad of the printed circuit board in an incorrect position, which cause a misalignment between the electronic component and the pad.

What is needed, therefore, is an apparatus and a method for surface mounting process, thereby registering the electronic component with the corresponding pad of the printed circuit board exactly.

### SUMMARY

One present embodiment provides an apparatus for surface mounting an electronic component onto a pad of a printed circuit board. The apparatus includes a platform, a first image sensing device, a second image sensing device, a picking-up/placing device and a central processing device. The platform has a supporting surface configured for placing the electronic component and the printed circuit board thereon. The first image sensing device is configured for capturing an outline image of the electronic component that is taken normal to the supporting surface. The second image sensing device is configured for capturing an outline image of the pad that is taken normal to the supporting surface. The picking-up/placing device configured for picking up the electronic component and placing the electronic component onto the pad. The central processing device electronically coupled to the first image sensing device, the second image sensing device and the picking-up/placing device. The central processing device is configured for controlling the first image sensing device and the second image sensing device to capture the outline images, determining a coordinate of a geometrical center of the electronic component and a coordinate of a geometrical center of the pad, and controlling the picking-up/placing device to move the electronic component onto the pad according to the coordinate of the geometrical center of the electronic component and the coordinate of the geometrical center of the pad.

Another present embodiment provides a method for surface mounting an electronic component onto a pad of a printed circuit board. The method includes the following steps. Firstly, the electronic component and the printed circuit board are located onto a supporting surface of a platform. Secondly, an outline image of the electronic component taken normal to the supporting surface is captured using a first image sensing device. A coordinate of a geometrical center of the electronic component is determined using a central processing device according to information of the outline image of the electronic component. Thirdly, an outline image of the pad taken normal to the supporting surface is captured using a second image sensing device. A coordinate of a geometrical center of the pad is determined using the central processing device according to the outline image of the pad. The coordinate of the geometrical center of the electronic component and the coordinate of the geometrical center of the pad are determined in a common Cartesian coordinates system. Fourthly, the electronic component is moved on to the pad using a picking-up/placing device according to the coordinate of the geometrical center of the electronic component and the coordinate of the geometrical center of the pad.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a schematic view of a surface mounting apparatus according to a present embodiment.

FIG. 2 is a schematic view of another surface mounting apparatus according to the present embodiment.

FIG. 3 is a schematic, top view of an electronic component to be mounted placed onto a supporting surface of the platform according to the present embodiment.

FIG. 4 is a schematic, top view of a printed circuit board placed onto a supporting surface of the platform, which will be mounted the electronic component in FIG. 3 thereon, according to the present embodiment.

FIG. 5 is a flow chart of a surface mounting method according to the present embodiment.

### DETAILED DESCRIPTION OF THE EMBODIMENTS

Embodiment will now be described in detail below and with reference to the drawings.

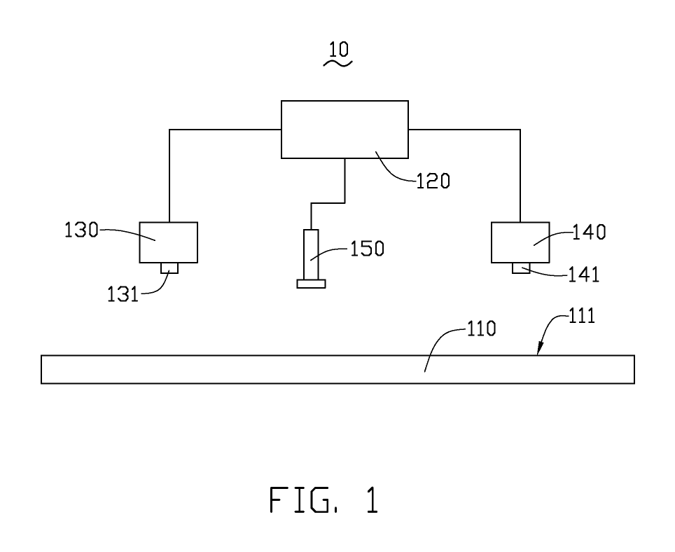

Referring to FIG. 1, a first exemplary apparatus 10 for a surface mounting process includes a platform 110, a central processing device 120, a first image sensing device 130, a second image sensing device 140 and a picking-up/placing device 150.

The platform 110 is arranged and structured for holding objects such as an electronic component and a printed circuit board. The platform 110 has a supporting surface 111 that is opposite to the first image sensing device 130, the second image sensing device 140 and the picking-up/placing device 150.

The central processing device 120 electronically coupled to the first image sensing device 130, the second image sensing device 140 and the picking-up/placing device 150 respectively so as to control the first image sensing device 130, the second image sensing device 140 and the picking-up/placing device 150 to function. For example, the central processing device 150 is configured for controlling the first image sensing device 130 and the second image sensing device 140 to move to predetermined positions so as to sense and capture images of the objects placed on the platform 110. The central processing device 150 is also configured for controlling the picking-up/placing device 150 to move to a predetermined position, to pick up the one of the objects on the platform 110 and place the one of the objects on the other one of the objects on the platform 110. Additionally, the central processing device 150 is also configured for processing information of images of the sensed objects, thereby obtaining a coordinate of a geometrical center of each of the sensed objects in a common Cartesian coordinates system.

The first image sensing device 130 includes a first image sensor 131. The second image sensing device 140 includes a second image sensor 141. The first image sensor 131 and the second image sensor 141 can be a charged coupled device (CCD). The first image sensing device 130 and the second image sensing device 140 are configured for sensing and capturing images of the objects placed on the platform 110. The first image sensing device 130 and the second image sensing device 140 can move along a peripheral edge of the object to be sensed, and sense and capture an outline image of the sensed object that is taken normal to the supporting surface 111. The outline image can be either an entire outline image or a segmentary outline image. The segmentary outline image should be enough to calculated a coordinate of a geometrical center of the sensed object. In the present embodiment, the segmentary outline image of the sensed object refers to the outline images of two symmetrical end portions of the sensed object, which is sensed and captured by the first image sensor 131 or the second image sensor 141. Information of the outline image of each of the sensed objects is then transmitted to the central processing device 120 to be processed.

The picking-up/placing device 150 is configured for picking-up and placing one of the objects placed on the platform 110. The picking-up/placing device 150 can move to a predetermined position, pick-up the one of the objects placed on the platform 110 to move from one position to another position, and place the one of the objects on the other one of the objects placed on the platform 110. The picking-up/placing device 150 can be operated in a vacuum absorption manner or in a mechanical manner.

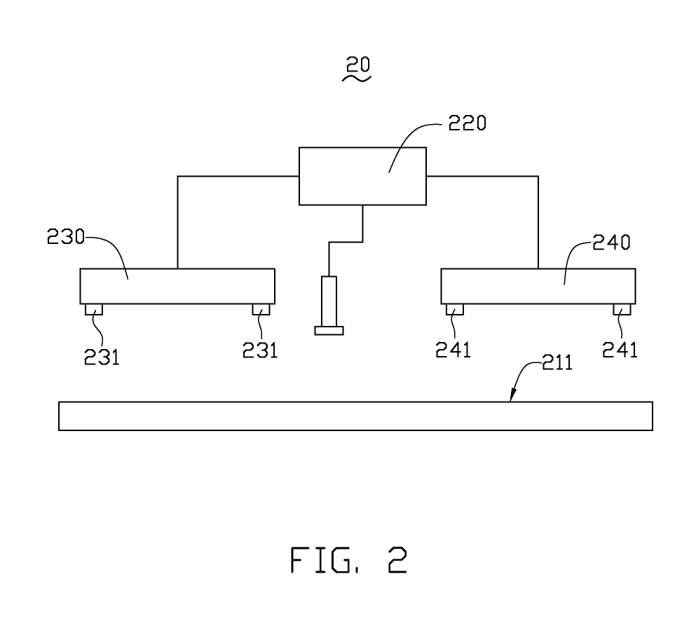

Referring to FIG. 2, a second exemplary surface mounting apparatus 20 is shown. The second surface mounting apparatus 20 is similar to the first surface mounting apparatus 10 except that a first image sensing device 230 has two first image sensors 231 and a second image sensing device 240 has two second image sensors 241. A distance of the two first image sensors 231 can be adjusted under a control of the central processing device 220 so that the two first image sensors 231 can be respectively located at two positions of a peripheral edge of the sensed object taken normal to the supporting surface 111 by the first image sensing device 230. Thus, the two first image sensors 231 can sense and capture segmentary outline images of the sensed object by the first image sensing device 230. Similarly, a distance of the two second image sensors 241 can also be adjusted under a control of the central processing device 220 so that the two second image sensors 241 can be respectively located at two positions of a peripheral edge of the sensed object taken normal to the supporting surface 111 by the second image sensing device 240. Thus, the two second image sensors 241 can sense and capture segmentary outline images of the sensed object by the second image sensing device 240 simultaneously.

It is noted that the first image sending device 230 can have a number of first image sensors 231. The first image sensors 231 can be adjusted under a control of the central processing device 220 so that the first image sensors 231 can be arranged along the peripheral edge of the sensed object taken normal to the supporting surface 111 by the first image sensing device 230. Thus, the first image sending device 230 can sense and capture the outline image of the sensed object by the first image sensing device 230. Similarly, the second image sending device 240 can include a number of second image sensors 241. The second image sensors 241 can be adjusted under a control of the central processing device 220 so that the second image sensors 241 can be arranged along the peripheral edge of the sensed object taken normal to the supporting surface 111 by the second image sensing device 240. Thus, the second image sending device 240 can sense and capture the outline image of the sensed object by the second image sensing device 240. It is also noted that a number of the first image sensor 231 of the first image sensing device 230 can be different from that of the second image sensors 241 of the second image sensing device 240.

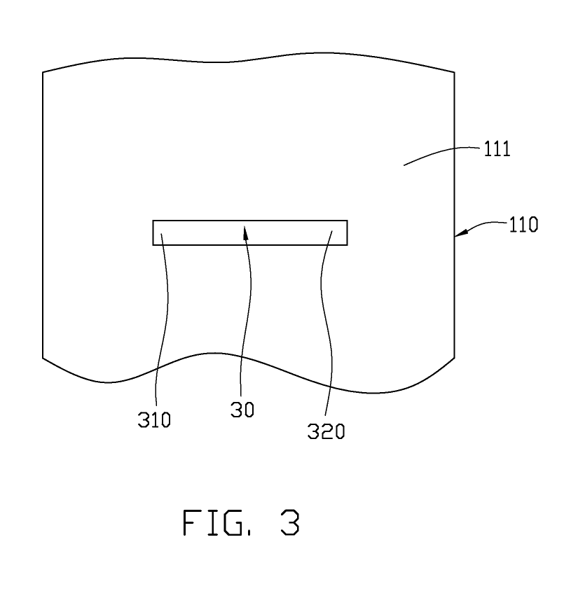

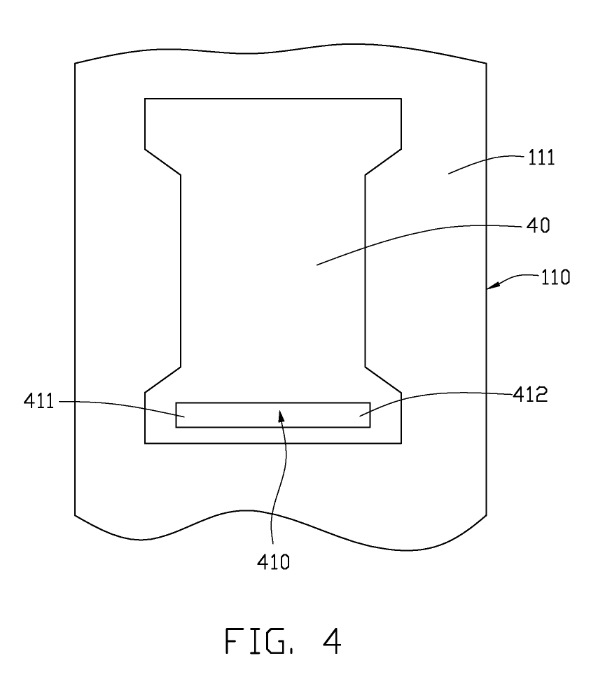

In the present embodiment, two objects is registered using the first surface mounting apparatus 10. Referring to FIGS. 3 and 4, the two objects placed on the platform 110 of the first registering apparatus 10 includes an electronic component 30 to be mounted and a printed circuit board 40 having a pad 410 thereon. The electronic component 30 can be registered and mounted onto the pad 410 of the printed circuit board 40 using the first surface mounting apparatus 10.

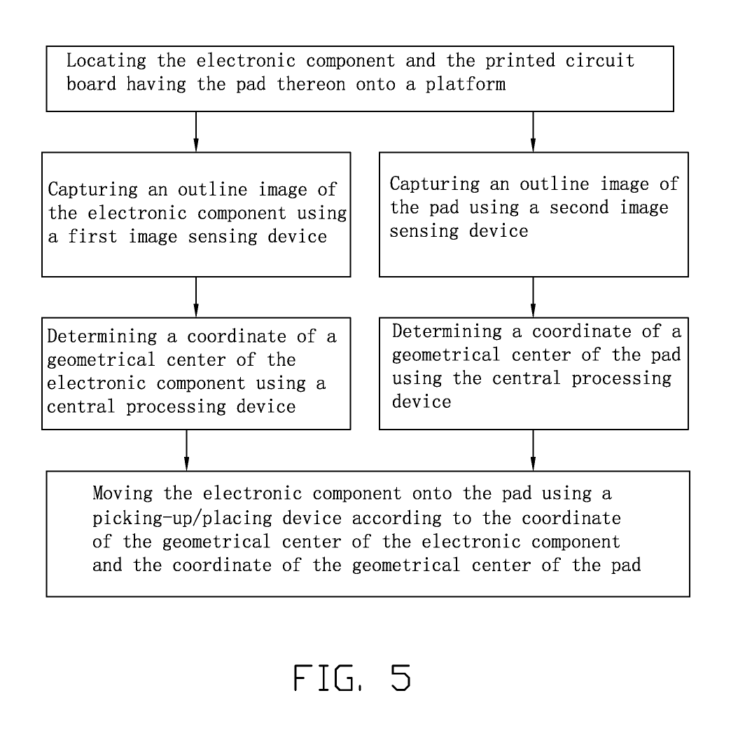

Referring to FIG. 5, an exemplary method for surface mounting the electronic component 30 onto the pad 410 of the printed circuit board 40 includes the following steps.

Step 1: the electronic component 30 and the printed circuit board 40 are located on the platform 110.

The electronic component 30 and the printed circuit board 40 can be directly placed on the platform 110 of the first exemplary registering apparatus 10 simultaneously. Preferably, a number of electronic components 30 can be fixed on a corresponding supporting device at first, and then the corresponding supporting device can be placed on the platform 110. Preferably, a number of printed circuit boards 40 also can be fixed on a corresponding supporting device, and then the corresponding supporting device can be placed on the platform 110. In the present embodiment, the electronic component 30 is directly located on the platform 110 so that the first image sensing device 130 can sense and capture an outline image of the electronic component 30 taken normal to the supporting surface 111. The printed circuit board 40 is directly located on the platform 110 so that the second image sensing device 140 can sense and capture an outline image of the pad 410 taken normal to the supporting surface 111.

Referring to FIG. 3, the electronic component 30 has a large size, for example, a connector. A configuration of the electronic component 30 has a rectangular shape in a top view. The electronic component 30 has a first end portion 310 and a second portion 320. The first end portion 310 and the second end portion 320 are symmetrical to each other.

Referring to FIG. 4, the printed circuit board 40 can be a rigid printed circuit board or a flexible printed circuit board. The printed circuit board 40 has a pad 410 thereon. A size and a configuration of the pad 410 correspond to those of the electronic component 30. In the present embodiment, the pad 410 has a rectangular shape corresponding to the electronic component 30 in rectangular shape. The pad 410 has a first end section 411 and a second section 412. The first end section 411 and the second end section 412 are symmetrical to each other.

Step 2: an outline image of the electronic component 30 taken normal to the supporting surface 111 is captured using a first image sensing device 130. A coordinate of a geometrical center of the electronic component 30 is determined using a central processing device 120 according to information of the outline image of the electronic component 30.

Firstly, the central processing device 120 controls the first image sensor 131 of the first image sensing device 130 to move to the first end portion 310 of the electronic component 30 so that the first image sensor 131 senses and captures an outline image of the first end portion 310 that is taken normal to the supporting surface 111. Information of the outline image of the first end portion 310 sensed then is transmitted to the central processing device 120 to be processed, thereby obtaining coordinates of the outline image of the first end portion 310 that is taken normal to the supporting surface 111.

Secondly, the central processing device 120 controls the first image sensor 131 of the first image sensing device 130 to move to the second end portion 320 of the electronic component 30 so that the first image sensor 131 senses and captures an outline image of the second end portion 320 that is taken normal to the supporting surface 111. Information of the outline image of the second end portion 320 sensed then ise transmitted to the central processing device 120 to be processed, thereby obtaining coordinates of the outline image of the second end portion 320 that is taken normal to the supporting surface 111. Coordinates of the outline image of the first end portion 310 that is taken normal to the supporting surface 111 and coordinates of the outline image of the second end portion 320 that is taken normal to the supporting surface 111 are calculated in a common Cartesian coordinates system. According to these information sensed, a coordinate of a geometrical center of the electronic component 30 can be calculated using the central processing device 120.

It is noted that the central processing device 120 can control the first image sensor 131 of the first image sensing device 130 to move along an entire peripheral edge of the electronic component 30. Thus, more information of the outline image of the electronic component 30 that is taken normal to the supporting surface 111 can be obtained so as to calculate exact the coordinate of the geometrical center of the electronic component 30.

Step 3: an outline image of the pad 410 taken normal to the supporting surface 111 is captured using a second image sensing device 140. A coordinate of a geometrical center of the pad 410 is determined using the central processing device 120 according to the outline image of the pad 410. The coordinate of the geometrical center of the electronic component 30 and the coordinate of the geometrical center of the pad 410 are determined in a common Cartesian coordinates system.

Firstly, the central processing device 120 controls the second image sensor 141 of the second image sensing device 140 to move to the first end section 411 of the pad 410 so that the second image sensor 141 senses and captures an outline image of the first end section 411 that is taken normal to the supporting surface 111. Information of the outline image of the first end section 411 sensed then is transmitted to the central processing device 120 to be processed, thereby obtaining coordinates of the outline image of the first end section 411 that is taken normal to the supporting surface 111. Coordinates of the outline image of the first end section 411 that is taken normal to the supporting surface 111 and coordinates of the outline image of the first end portion 310 and the second end portion 320 that is taken normal to the supporting surface 111 are calculated in the common Cartesian coordinates system.

Secondly, the central processing device controls the second image sensor 141 of the first image sensing device 140 to move to the second end section 412 of the pad 410 so that the second image sensor 141 senses and captures an outline image of the second end section 412 that is taken normal to the supporting surface 111. Information of the outline image of the second end section 412 sensed then is transmitted to the central processing device 120 to be processed, thereby obtaining coordinates of the outline image of the second end section 412 that is taken normal to the supporting surface 111. Coordinates of the outline image of the second end section 412 that is taken normal to the supporting surface 111 and coordinates of the outline image of the first end portion 310 and the second end portion 320 that is taken normal to the supporting surface 111 are also calculated in the common Cartesian coordinates system. According to these information sensed, the coordinate of a geometrical center of the pad 410 can be calculated using the central processing device 120.

It is noted that the central processing device 120 can control the second image sensor 141 of the second image sensing device 140 to move along an entire peripheral edge of the pad 410. Thus, more information of the outline image of the pad 410 that is taken normal to the supporting surface 111 can be obtained so as to calculate exact the coordinate of the geometrical center of the pad 410.

Step 4: the electronic component 30 is moved on to the pad 410 using a picking-up/placing device 150 according to the coordinate of the geometrical center of the electronic component 30 and the coordinate of the geometrical center of the pad 410.

The electronic component 30 is picked up and placed onto the pad 410 using a picking-up/placing device 150 according to the coordinate of the geometrical center of the electronic component 30 and the pad 410. Firstly, the central processing device 120 controls the picking-up/placing device 150 to move so that an axis of the picking-up/placing device 150 is moved to the coordinate of the geometrical center of the electronic component 30. When the axis of the picking-up/placing device 150 arrives at the coordinate of the geometrical center of the electronic component 30, the central processing device 120 controls the picking-up/placing device 150 to pick up the electronic component 30.

Secondly, the central processing device 120 controls the picking-up/placing device 150 to move so that the axis of the picking-up/placing device 150 is moved to the coordinate of the geometrical center of the pad 410. When the axis of the picking-up/placing device 150 arrives at the coordinate of the geometrical center of the pad 410, the central processing device 120 controls the picking-up/placing device 150 to place the electronic component 30 onto the pad 410. As a result, the geometrical center of the electronic component 30 is superposed the geometrical center of the pad 410, and thus the electronic component 30 is registered with the pad 410 of the printed circuit board 40 for a mounting process.

The second surface mounting apparatus 20 also can be used in the present registering method. It is noted that there are some differences between the method using the first surface mounting apparatus 10 and the method using the second surface mounting apparatus 20. In the present method using the second surface mounting apparatus 20, the central processing device 220 controls the two first image sensing device 230 to adjust the distance of the two first image sensors 231 so that the two first image sensors 231 can senses and captures the outline images of the first end portion 310 and the second end portion 320 of the electronic component 30 that are taken normal to the supporting surface 211 simultaneously. Similarly, the central processing device 220 controls the two second image sensing device 240 to adjust the distance of the two second image sensors 241 so that the two second image sensors 241 can senses and captures the outline images of the first end section 411 and the second end section 412 of the pad 410 that are taken normal to the supporting surface 211 simultaneously.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A method for surface mounting an electronic component onto a pad of a printed circuit board, the method comprising the steps of:
locating the electronic component and the printed circuit board onto a supporting surface of a platform;
capturing an outline image of the electronic component using a first image sensing device, the outline image of the electronic component being taken normal to the supporting surface;
determining a coordinate of a geometrical center of the electronic component using a central processing device according to the outline image of the electronic component;
capturing an outline image of the pad, the outline image of the pad being taken normal to the supporting surface using a second image sensing device;
determining a coordinate of a geometrical center of the pad using the central processing device according to the outline image of the pad, wherein the coordinate of the geometrical center of the electronic component and the coordinate of the geometrical center of the pad are calculated in a common Cartesian coordinates system; and
moving the electronic component onto the pad using a picking-up/placing device according to the coordinate of the geometrical center of the electronic component and the coordinate of the geometrical center of the pad.

2. The method as claimed in claim 1, wherein the outline image of the electronic component is an image of the entire electronic component taken normal to the supporting surface.

3. The method as claimed in claim 2, wherein the outline image of the electronic component is captured by moving the first image sensing device along an entire peripheral edge of the electronic component under a control of the central processing device.

4. The method as claimed in claim 3, wherein the outline image of the pad is captured by moving the second image sensing device along an entire peripheral edge of the pad under a control of the central processing device.

5. The method as claimed in claim 1, wherein the outline image of the electronic component is formed by combining a plurality of segmentary outline images of each of portions of the electronic component that are taken normal to the supporting surface.

6. The method as claimed in claim 5, wherein the segmentary outline images comprises an outline image of a first end portion of the electronic component and an outline image of an opposite second end portion of the electronic component, the first end portion and the second end portion are symmetrical to each other, the first image sensor is moved under a control of the central processing device to respectively capture the outline image of the first end portion of the electronic component and the outline image of a second end portion of the electronic component.

7. The method as claimed in claim 6, wherein the outline image of a first end portion of the electronic component and the outline image of a second end portion of the electronic component are simultaneously captured.

8. The method as claimed in claim 1, wherein the outline image of the pad is formed by combining a plurality of segmentary outline images of each of portions of the pad that are taken normal to the supporting surface.

9. The method as claimed in claim 8, wherein the segmentary outline images comprising an outline image of a first end section of the pad and an outline image of an opposite second end section of the pad, the first end section and the second end section are symmetrical to each other, the second image sensor is moved under a control of the central processing device to respectively capture the outline image of the first end section of the pad and the outline image of a second end section of the pad.

10. The method as claimed in claim 8, wherein the outline image of the first end section of the pad and the outline image of the second end section of the pad are simultaneously captured.

11. An apparatus for surface mounting an electronic component onto a pad of a printed circuit board, the apparatus comprising:
a platform having a supporting surface, the supporting surface being configured for placing the electronic component and the printed circuit board thereon;
a first image sensing device configured for capturing an outline image of the electronic component that is taken normal to the supporting surface;
a second image sensing device configured for capturing an outline image of the pad that is taken normal to the supporting surface;
a picking-up/placing device configured for picking up the electronic component and placing the electronic component onto the pad; and
a central processing device electronically coupled to the first image sensing device, the second image sensing device and the picking-up/placing device, the central processing device being configured for controlling the first image sensing device and the second image sensing device to capture the outline images, determining a coordinate of a geometrical center of the electronic component and a coordinate of a geometrical center of the pad, and controlling the picking-up/placing device to move the electronic component onto the pad according to the coordinate of the geometrical center of the electronic component and the coordinate of the geometrical centers of the pad.

12. The apparatus as claimed in claim 11 wherein the first image sensing device comprises a plurality of first image sensors, the first image sensors being movably arranged along a peripheral edge of the electronic component so that the outline image of the electronic component that is taken normal to the supporting surface is captured.

13. The apparatus as claimed in claim 12, wherein the second image sensing device comprises a plurality of second image sensors, the second image sensors are movably arranged along a peripheral edge of the pad so that the outline image of the pad that is taken normal to the supporting surface is captured.
